(19) United States
(12) Patent Application Publication
(10) Pub. No.: US 2024/0234101 A1
(43) Pub. Date: Jul. 11, 2024

(54) PLASMA SUBSTRATE TREATMENT APPARATUS

(71) Applicant: INNOVATION FOR CREATIVE DEVICES CO., LTD., Anseong-si (KR)

(72) Inventors: Buil JEON, Anseong-si (KR); Taeho SHIN, Yongin-si (KR); Dooho LIM, Suwon-si (KR); Jungsu PARK, Pyeongtaek-si (KR); Bumsoo ON, Yongin-si (KR); Seungho LEE, Yongin-si (KR)

(21) Appl. No.: 18/613,512

(22) Filed: Mar. 22, 2024

Related U.S. Application Data
(63) Continuation of application No. PCT/KR2022/015701, filed on Oct. 17, 2022.

(30) Foreign Application Priority Data
Oct. 20, 2021 (KR) 10-2021-0139971

(51) Int. Cl. H01J 37/32

(52) U.S. Cl. CPC H01J 37/32633; H01J 37/321; H01J 37/32146; H01J 37/32357; H01J 2237/0203; H01J 2237/3343

(57) ABSTRACT

A plasma substrate treatment apparatus according to one embodiment of the present invention comprises: a remote plasma generator for generating plasma and an active species; an upper chamber having an opening connected to an output port of the remote plasma generator and receiving and diffusing the active species of the remote plasma generator; a first baffle disposed on the opening of the upper chamber; a lower chamber receiving the diffused active species from the upper chamber; a second baffle partitioning the upper chamber and the lower chamber and transmitting the active species; a substrate holder for supporting a substrate disposed in the lower chamber; and an RF power source applying RF power to the substrate holder.

### CROSS-REFERENCE TO RELATED APPLICATIONS

This application is a continuation of and claims priority to PCT/KR2022/015701 filed on Oct. 17, 2022, which claims priority to Korea Patent Application No. 10-2021-0139971 filed on Oct. 20, 2021, the entireties of which are both hereby incorporated by reference.

### TECHNICAL FIELD

The present disclosure relates to a plasma apparatus, and relates to a plasma substrate apparatus for treating a substrate by receiving radicals generated from a remote plasma generator and diffusing in an upper chamber and providing the received radicals to an lower chamber, and generating capacitively-coupled plasma within a lower chamber.

### BACKGROUND ART

Plasma treatment devices are used for etching, cleaning, surface treatment, or the like. For example, plasma etching treatment devices require independent control of active species density, plasma density, and ion energy to obtain high etching selectivity and etching rate. A low-frequency RF power source below a band of several MHz is mainly used to control ion energy, and a high-frequency RF power source above a band of tens of MHz is mainly used to control plasma density and active species density. In addition, power of the low-frequency RF power source is increased to increase ion energy. Increasing the power of the high-frequency RF power source is required to increase plasma density. However, increasing the power of the high-frequency RF power source may cause gases to be over-decomposed, which may reduce etching selectivity. An electrostatic chuck is easily damaged by a high voltage.

Pulse plasma may change plasma characteristics by turning RF power on and off to reduce electron temperature and plasma density in a power-off interval. Accordingly, pulse plasma may reduce notching and bowing.

A conventional plasma device having a dual chamber structure includes an upper chamber and a lower chamber separated by a diffusion plate. Each of the upper and lower chambers generates plasma, and the diffusion plate separates each plasma region and is used as a path for movement of active species. Due to non-uniformity of the plasma in the upper chamber, the diffusion plate makes it difficult to control spatially uniform active species in the lower chamber. A structure of the diffusion plate for preventing mutual plasma diffusion makes it difficult to control pressure independently. Accordingly, the upper and lower chambers have limitations in securing desired plasma characteristics. The diffusion plate has a through-hole having a sufficiently small diameter to prevent mutual leakage of the upper and lower plasmas. Thus, conductance of the diffusion plate is reduced, the active species are deposited on the diffusion plate as foreign subjects, and the deposited foreign subjects may be separated to release contaminated particles. In addition, the plasma in the lower chamber interferes with the plasma in the upper chamber, and the plasma in the lower chamber has difficulty in plasma spatial uniformity due to non-uniformity of active species, or the like.

### DISCLOSURE OF THE INVENTION

### Technical Problem

The present disclosure provides a substrate treatment apparatus providing a uniform plasma process using a remote plasma source.

### Technical Solution

A plasma substrate treatment apparatus according to an embodiment includes: a remote plasma generator generating plasma and active species; an upper chamber having an opening connected to an output port of the remote plasma generator and receiving and diffuses the active species of the remote plasma generator; a first baffle disposed on the opening of the upper chamber; a lower chamber receiving the diffused active species from the upper chamber; a second baffle partitioning the upper chamber and the lower chamber and transmitting the active species; a substrate holder supporting a substrate disposed in the lower chamber; and a radio-frequency (RF) power source applying RF power to the substrate holder.

In an embodiment, the second baffle may include: an upper baffle electrically grounded and comprising a plurality of first through-holes opposing the upper chamber; and a lower baffle electrically grounded and spaced apart from the upper baffle and comprising a plurality of second through-holes.

In an embodiment, the second through-holes may be disposed to avoid overlapping the first through-holes.

In an embodiment, a diameter of the second through-hole may be greater than twice a thickness of the plasma sheath between the lower baffle and the plasma, and the plasma may permeate into the second through-hole.

In an embodiment, a gap between the upper baffle and the lower baffle may be less than or equal to several millimeters, and a gap between the substrate holder and a lower surface of the upper baffle may be greater than the gap between the upper baffle and the lower baffle.

In an embodiment, a diameter of the first through-hole of the upper baffle may be smaller than a diameter of the second through-hole of the lower baffle.

In an embodiment, the second through-hole may be disposed to avoid overlapping the first through-hole.

In an embodiment, a diameter of the upper baffle may be smaller than a diameter of the lower baffle.

In an embodiment, the first baffle may include: a disk having an inclined outer surface; and a ring plate having an inclined inner surface and an inclined outer surface and disposed to surround the disk at a predetermined gap from the disk. The outer surface of the disc may have an outer diameter increasing with height, and the inner surface of the ring plate may have an inner diameter increasing with height.

In an embodiment, the disk and the ring plate may be fixed by a plurality of bridges, and the ring plate may be fixed to the upper chamber by a plurality of columns.

In an embodiment, the first baffle may include a plurality of through-holes, through-holes disposed in a center portion of the first baffle may be holes inclined toward a central axis, and through-holes disposed at an edge of the first baffle may be holes inclined towards an outer side.

In an embodiment, the plasma substrate treatment apparatus may further include at least one ground ring. The ground ring may be disposed below the second baffle to surround plasma between the substrate holder and the second baffle and has a ring shape, and an inner diameter of the ground ring may be greater than an outer diameter of the substrate holder.

In an embodiment, the second baffle may include: an upper baffle electrically grounded and comprising a plurality of first through-holes opposing the upper chamber; and a lower baffle electrically grounded and spaced apart from the upper baffle and comprising a plurality of second through-holes. The lower baffle may include: a perforated plate formed of a conductor; and a compensation plate disposed below the perforated plate and being an insulator having a dielectric constant or a semiconductor. The second through-holes of the lower baffle may be disposed to penetrate through the perforated plate and the compensation plate.

In an embodiment, the lower baffle may have a constant thickness, a thickness of the perforated plate may vary depending on a location, and a thickness of the compensation plate may vary depending on a location to maintain the thickness of the lower baffle constant.

In an embodiment, the compensation plate may include at least one of silicon, silicon oxide, silicon nitride, or silicon oxynitride.

In an embodiment, the thickness of the compensation plate may be greatest in at least one of a central region and an edge region, the central region may have a circular shape, and the edge region may have a ring shape.

In an embodiment, the RF power source may include: a low-frequency RF power source of 13.56 MHz or less; and a high-frequency RF power source of more than 13.56 MHz and less than 60 MHz.

In an embodiment, plasma substrate treatment apparatus may further include: a pulse control controlling the low-frequency RF power and the high-frequency RF power, and each of the low-frequency RF power and the high-frequency RF power may operate in pulse mode.

In an embodiment, the remote plasma generator may be an inductively-coupled plasma source including an induction coil wound around a dielectric cylinder.

In an embodiment, the diameter of the output port of the remote plasma generator may range from 50 millimeters to 150 millimeters, the upper chamber may have a truncated cone shape, and the opening of the upper chamber may be disposed in a truncated portion.

### Advantageous Effects

As set forth above, a plasma substate treatment apparatus according to an example embodiment may control plasma characteristics independently and provide a uniform process.

### BRIEF DESCRIPTION OF THE DRAWINGS

FIG. 1 is a conceptual diagram of a plasma substrate treatment apparatus according to an embodiment of the present disclosure.

FIG. 2A is a perspective view of a first baffle in the plasma substrate treatment apparatus of FIG. 1.

FIG. 2B is a cross-sectional view of the first baffle of FIG. 2A.

FIG. 3A is a plan view of a second baffle in the plasma substrate treatment apparatus of FIG. 1.

FIG. 3B is a cross-sectional view of the second baffle, cut along line A-A′ of FIG. 3A.

FIG. 4 is a conceptual diagram of a substrate holder and a second baffle of the plasma substrate treatment apparatus of FIG. 1.

FIG. 5a is a perspective view of a second baffle according to an embodiment of the present disclosure.

FIG. 5b is a cross-sectional view of a second baffle according to an embodiment of the present disclosure.

FIG. 6 is a plan view of a second baffle according to another example embodiment of the present disclosure.

FIG. 7 is a conceptual diagram of a second baffle according to another embodiment of the present disclosure.

FIG. 8 is a cut-away perspective view of a lower baffle of the second baffle of FIG. 7.

FIG. 9 is a diagram illustrating a change in plasma density by the second baffle of FIG. 7.

FIG. 10 is a conceptual diagram of a substrate treatment apparatus according to another embodiment of the present disclosure.

FIG. 11 is a cross-sectional view of a first baffle according to another embodiment of the present invention.

FIG. 12 is a cross-sectional view of a first baffle according to another embodiment of the present invention.

FIG. 13 is a diagram illustrating a low-frequency RF signal and a high-frequency RF signal of an RF power source according to another embodiment of the present disclosure.

### MODE FOR CARRYING OUT THE INVENTION

A plasma substrate treatment apparatus according to an embodiment may use a remote plasma generator, spatially separated from a process chamber, to independently generate plasma and active species and supply only active species to an upper chamber constituting the process chamber. A remote plasma generator may independently generate active species and plasma, and may not interfere with RF power of the process chamber.

The process chamber may include an upper chamber and a lower chamber. Active species supplied to the upper chamber may be injected and diffused to a wide region by a first baffle, and the upper chamber may provide a sufficient space for diffusion. A second baffle, disposed between the upper and lower chambers, may have an optimized structure that may block charged particles such as ions and electrons generated in the lower chamber while allowing active species in the upper chamber to pass through to the lower chamber. The second baffle may move active species to the lower chamber without loss, and maydiffuse the active species in a shortest distance and uniformly inject the diffused active species into the lower chamber.

A plasma treatment apparatus according to an embodiment may use a remote plasma generator to independently generate active species and supply the generated active species to a process chamber including an upper chamber and a lower chamber. The remote plasma generator may eliminate electrical interference with the process chamber, and may independently generate active species under optimal plasma conditions. A first baffle may remove the plasma supplied by the remote plasma generator and supply only active species to the upper chamber. The first baffle may inject and diffuses the active species over a large area. The upper and lower chambers are separated by a second baffle. The active species in the upper chamber may be supplied to the lower chamber through the grounded second baffle. A substrate holder may be disposed in the lower chamber, and RF power applied to the substrate holder may generate capacitively-coupled plasma between the substrate on the substrate holder and the second baffle (ground). As the active species are independently supplied to the lower chamber, power of a high-frequency RF power source for generating active species in the lower chamber may be reduced. In addition, power of a low-frequency RF power source for controlling ion energy may be reduced to be mainly used to adjust the ion energy.

In the plasma substrate treatment apparatus according to an embodiment, the first baffle may distribute the active species spatially uniformly, and the second baffle may be used as a ground electrode for the capacitively-coupled plasma generated in the lower chamber. The second baffle has a multilayer structure with an upper baffle and a lower baffle spaced apart from each other. The lower baffle of the second baffle may have a sufficient diameter to allow plasma to permeate from a lower side, and the plasma permeating through an opening of the lower baffle may be blocked by the upper baffle. The upper and lower baffles of the second baffle are both grounded to increase a surface area of ground that is in contact with the plasma, and a bias voltage applied to a plasma sheath on a substrate side may be increased. Accordingly, the power of the low-frequency RF power source for controlling ion energy incident on the substrate may be reduced.

Charged particles (ions and electrons) become neutral when they collide with a wall. Accordingly, a method of blocking ions or electrons involves ensuring that there are no through-holes so that the ions or electrons collide when passing through the second baffle. In contrast, neutral species or active species do not lose much of their reactivity in collisions. The Charged particles become neutral by collision while moving from a lower portion to an upper portion, and neutral species may move an upper portion to a lower portion with minimal collision. To this end, the second baffle has a multilayer structure to have large vacuum conductance, and an opening of the upper baffle and an opening of the lower baffle are designed so as not to overlap each other.

The second baffle may include an upper baffle and a lower baffle with a perforated plate structure. Each of the upper baffle and the lower baffle have a through-hole structure having various shapes such as a maximum-sized triangle, square, or circle. When a plurality of perforated plates are stacked to block the movement of charged particles, the perforated plates do penetrate from an upper portion to a lower portion. In other words, particles cannot move the upper portion to the lower portion without collision. The second baffle may be designed to have maximum vacuum conductance while having a structure in which particles cannot straightly move from a lower portion to an upper portion without collision. For example, when two perforated plates are used, each of the perforated plate may be provided such that an opening is maximized to have maximum conductance. When the two perforated plates are stacked, there is no overlapping opening (a penetrating portion).

In addition, a hole of the lower baffle may have a sufficient large diameter such that the plasma generated in the lower chamber pass through the lower baffle. For example, the hole of the lower baffle may have a diameter of several millimeters. The hole of the lower baffle may have a diameter of, in detail, 5 to 10 millimeters. The hole of the lower baffle may have a larger diameter than a hole of the upper baffle. Accordingly, the plasma incident on the lower baffle may be blocked and neutralized by the upper baffle. In addition, a contact area with the plasma may be increased.

According to an embodiment, the second baffle may include an upper baffle and a lower baffle spaced apart from each other, and the lower baffle may oppose a substrate to which the power of the RF power source is applied. Accordingly, a ratio of a surface area of the lower baffle contacting the plasma to an area of the substrate may depend on a voltage applied to the substrate. Accordingly, when the surface area of the lower baffle contacting the plasma increases, a DC bias voltage applied to the substrate may increase. As a result, higher ion energy may be obtained at the same RF power source.

According to an embodiment, the lower baffle of the second baffle may have a two-layer stacked structure. In the case of high-frequency RF plasma, a spatially non-uniform plasma density distribution may be formed due to a standing wave effect or a harmonic effect. For example, a spatial distribution in a plasma radial direction may have a central peak and/or an edge peak. However, the plasma density increases as the frequency of the RF power source increases, so that a high-frequency RF power source of 60 MHz or higher may be used. However, such high-frequency RF power source of 60 MHz or higher may generate a spatially non-uniform plasma density distribution due to the standing wave effect or harmonic effect. At least one ground ring may be disposed to surround a discharge region, thereby significantly reducing an effect on conductance of gas, increasing a resonant frequency to suppress the standing wave effect, and increasing a ground area.

According to an embodiment, a high-frequency RF power source of 60 MHz or higher may not be used to increase the plasma density with the help of a remote plasma generator.

According to an embodiment, even when a high-frequency RF power source of 60 MHz or lower is used, a central peak and/or an edge peak may be controlled. Spatial control of electric field strength may be performed by adjusting a gap distribution between an upper electrode (second baffle) and a lower electrode (substrate holder). When a step is provided on a lower surface of the grounded upper electrode (second baffle) to adjust a gap between the grounded upper electrode (second baffle) and the lower electrode (substrate holder), the step on the lower surface of the grounded upper electrode (second baffle) may affect conductance when the gas moves through the second baffle. In addition, the step on the lower surface of the upper electrode (second baffle) may act as an obstacle to a flow of gas in a discharge space. In addition, contaminants may be attached to a step portion of the lower surface of the upper electrode (second baffle).

According to an embodiment, the lower baffle of the second baffle may maintain a spatially uniform thickness to eliminate an effect on the conductance when the active species move through the lower baffle. In other words, the lower baffle may include an overlying conductive perforated plate and an underlying dielectric compensation plate. The lower baffle includes a compensation plate formed of an additional dielectric or semiconductor to remove the obstacle to the flow of the gas in the discharge space. A lower surface of the lower baffle may be the same plane. The closer the dielectric constant of the compensation layer is to the vacuum dielectric constant, the more advantageous it may be. The compensation layer may be silicon, silicon oxide, silicon nitride, silicon oxynitride, or aluminum oxide. A thickness of the compensation layer may vary depending on a location thereof. As the thickness of the compensation layer increases, electric field strength in the discharge space at the corresponding location may decrease. Accordingly, a spatial distribution of the thickness of the compensation layer may control the central peak and/or the edge peak. The compensation layer may be decomposed and combined with the conductive perforated plate of the lower baffle. The compensation layer may be a consumable and may be replaced with a new component.

According to an embodiment, the lower baffle may further include a plurality of trenches and/or holes formed on the lower baffle to increase the contact area with the plasma. The plurality of trenches and/or holes may increase the contact area with the plasma.

According to an embodiment, ring-shaped guard rings may be disposed to surround the discharge space between the second baffle and the substrate holder. The guard rings may be grounded to increase a grounding area of the plasma. In addition, the guard rings may be used to suppress plasma diffusion and confine the plasma within the discharge space. The guard rings may be stacked and grounded to perpendicular to each other. Process byproducts may diffuse through a space between the guard rings to be exhausted through a vacuum pump.

According to an embodiment, the high-frequency RF power source and low-frequency RF power source applied to the substrate holder may be synchronized with each other to operate in pulse mode. The high-frequency RF power source may include a high-power section and a low-power section, and the low-frequency RF power source may have an ON interval in a low-power section of the high-frequency RF power source.

The substrate treatment apparatus according to an embodiment may filter charged particles and use only active species having reactivity in etching, deposition, cleaning devices, or the like, in semiconductor processes.

The plasma substrate treatment apparatus according to an embodiment may be applied to an atomic layer etching apparatus, a plasma cleaning apparatus, a deposition apparatus using plasma, or the like, in semiconductor etching.

The first baffle may significantly reduce loss caused by collision while the active species diffuse downwardly, and may uniformly diffuse the active species from an upper area having a diameter of about 10 cm to a lower area having a diameter of about 40 cm in a shortest distance.

Hereinafter, example embodiments will now be described more fully with reference to the accompanying drawings, in which some example embodiments are shown. Example embodiments may however, be embodied in many different forms and should not be construed as being limited to the embodiments set forth herein. Rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements.

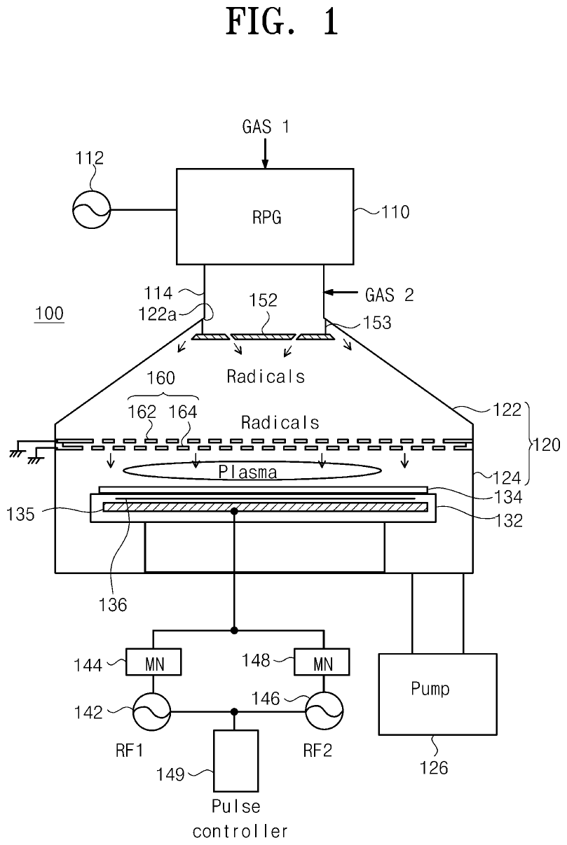

FIG. 1 is a conceptual diagram of a plasma substrate treatment apparatus according to an embodiment of the present disclosure.

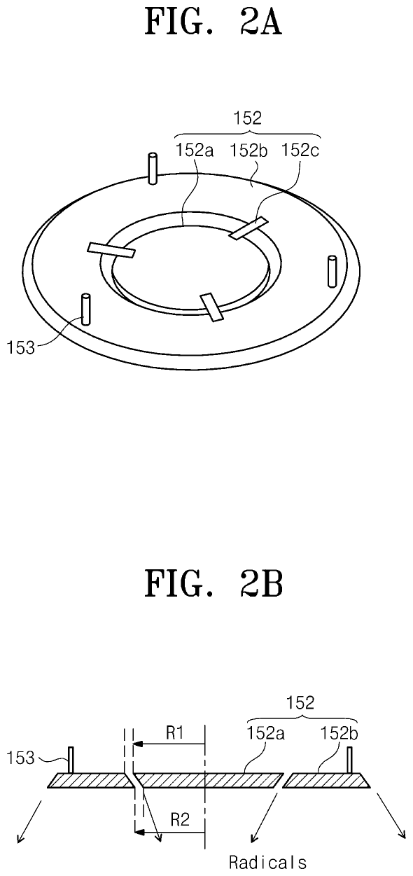

FIG. 2A is a perspective view of a first baffle in the plasma substrate treatment apparatus of FIG. 1.

FIG. 2B is a cross-sectional view of the first baffle of FIG. 2A.

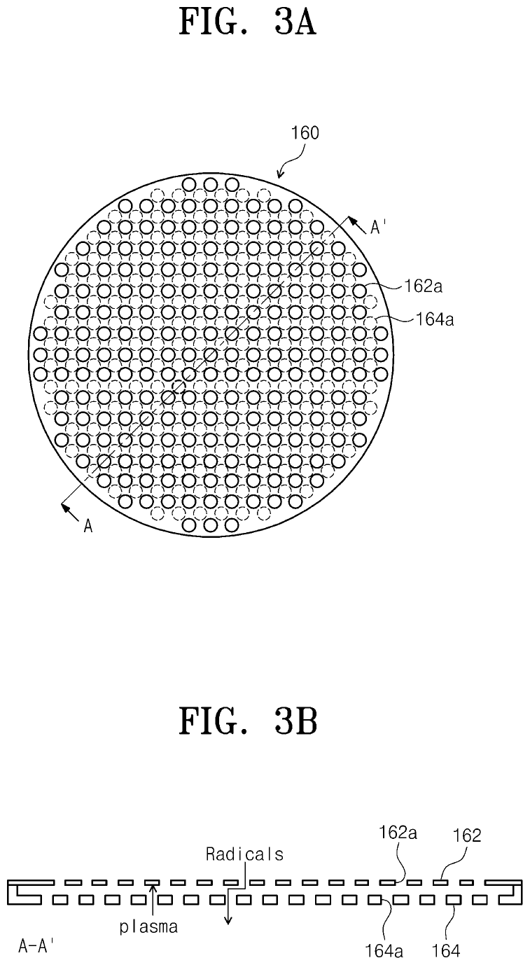

FIG. 3A is a plan view of a second baffle in the plasma substrate treatment apparatus of FIG. 1.

FIG. 3B is a cross-sectional view of the second baffle, cut along line A-A′ of FIG. 3A.

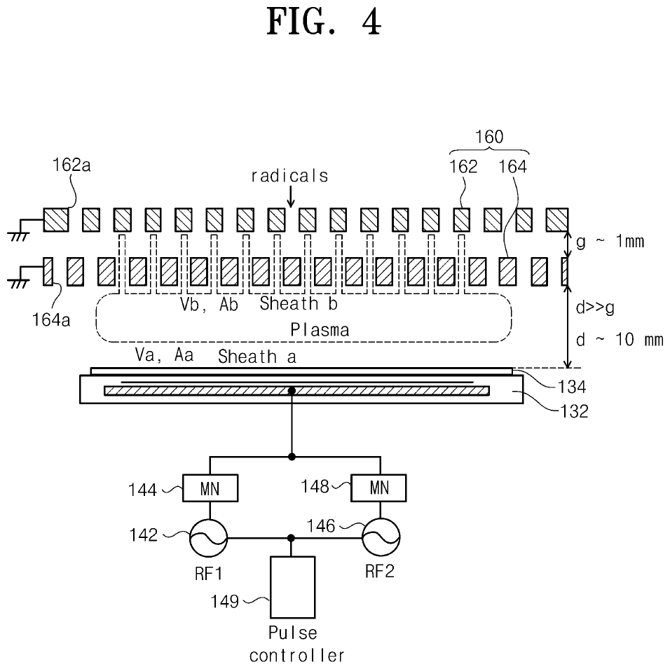

FIG. 4 is a conceptual diagram of a substrate holder and a second baffle of the plasma substrate treatment apparatus of FIG. 1.

Referring to FIGS. 1 to 4, a plasma substrate treatment apparatus 100 may include: a remote plasma generator 110 generating plasma and active species; an upper chamber 122 having an opening 120a connected to an output port 114 of the remote plasma generator 110 and receiving and diffusing the active species of the remote plasma generator 110; a first baffle 152 disposed on the opening of the upper chamber 122; a lower chamber 124 receiving the diffused active species from the upper chamber 122; a second baffle 160 partitioning the upper chamber 122 and the lower chamber 124 and transmitting the active species; a substrate holder 134 supporting a substrate 134 disposed in the lower chamber 160; and radio-frequency (RF) power sources 142 and 146 configure to apply RF power to the substrate holder 134.

The plasma substrate processing apparatus 100 may be an etching apparatus, a cleaning apparatus, a surface treatment apparatus, or a deposition apparatus. The substrate may be a semiconductor substrate, a glass substrate, or a plastic substrate.

The remote plasma generator 110 may be an inductively coupled plasma source including an induction coil (not illustrated) surrounding a dielectric cylinder. The dielectric cylinder may be supplied with a first gas from the outside. A diameter of the dielectric cylinder may be 50 mm to 150 nm. The induction coil may be wound around the dielectric cylinder at least one turn, and may be supplied with RF power from the remote plasma RF power source 112. A frequency of the remote plasma RF power source 112 may be 400 kHz to 13.56 MHz. The induction coil may generate an inductively coupled plasma inside the dielectric cylinder. An output of the remote plasma RF power source may be several kW to several tens of kW. Accordingly, an operating pressure of the remote plasma generator 110 may be several hundred milliTorr (mTorr) to several tens of Torr. In the case of an etching process, the first gas may include a fluorine-containing gas. The remote plasma generator 110 may generate plasma and active species (or neutral species) decomposed from the first gas. The remote plasma generator 110 may control only characteristics of the plasma without considering the uniformity of the plasma space. Electron temperature may depend on pressure, and plasma density may depend on the output of the remote plasma RF power source. The remote plasma RF power source 112 may operate in continuous mode or pulse mode to control the characteristics of the plasma. Accordingly, the remote plasma generator 110 may independently control the density of active species and a density ratio of the active species. For example, the remote plasma generator 110 may independently control the electron temperature using the pressure and the RF pulse mode. Accordingly, in CₓF_{y} gas, the density ratio of the decomposed active species F, CF, CF₂, and CF₃ may be controlled.

The active species are supplied to the process chamber 120. The process chamber 120 may include an upper chamber 122 and a lower chamber 124. The remote plasma generator 110 may be connected to the upper chamber 122 through the output port 114. A second gas may be additionally supplied to the output port 114. The second gas may be the same as or different from the first gas. The second gas may collide with the active species to reduce the temperature of the active species. The second gas may include at least one of oxygen-containing gas, hydrogen gas, and inert gas that is easy to generate plasma in the lower chamber.

The upper chamber 122 may have a truncated cone shape. The opening 122a of the upper chamber 122 may be disposed at the truncated portion. The lower portion of the upper chamber 122 may have a cylindrical shape. The upper chamber 122 may be formed of metal or metal-alloy, and may be grounded.

The first baffle 152 may include: a disk 152a having an inclined outer surface; and a ring plate 152b having an inclined inner surface and an inclined outer surface and disposed to surround the disk 152a at a predetermined gap from the disk 152a. The outer surface of the disc 152a may have an outer diameter increasing with height. The inner surface of the ring plate 152b may have an inner diameter increasing with height. The disk 152a and the ring plate 152b may be fixed by a plurality of bridges 152c. The ring plate 152b may be fixed to the upper chamber 122 by a plurality of columns 153.

A space between the disk 152a and the ring plate 152b may form a concentric slit. Active species passing through the concentric slit may be injected and diffused in a direction of a center of the upper chamber 122. The outer surface of the ring plate 152b may have an outer diameter decreasing with height. Active species passing through the space between the outer surface of the ring plate and the upper chamber may be injected and diffused in a direction of a wall of the upper chamber 122. Accordingly, the active species may be widely diffused within the upper chamber 122 to form a uniform density distribution. The first baffle 152 may spatially distribute the active species for rapid diffusion. Accordingly, the height of the upper chamber 122 may be reduced.

The first baffle 152 may be formed of a conductive material or an insulator. The first baffle 152 may act as a plasma blocking filter blocking plasma generated from the remote plasma generator 110 and transmitting active species. In addition, the first baffle 152 may perform a function of spatially distributing the active species. Vertically incident ions may collide with the inclined surface of the first baffle 152 while passing through the concentric slit of the first baffle 152. A maximum diameter R1 on the inclined outer surface of the disk 152a may be larger than a minimum diameter R2 on the inclined inner surface of the ring plate 152b.

According to a modified embodiment, the ring plate 152b may be provided in plural. Accordingly, the concentric slits between the ring plates 152b may block plasma through the inclined surface and inject the active species in a specific direction. As a result, the first baffle 152 may provide sufficient conductance by a plurality of concentric slits. The height of the upper chamber 122 may be reduced.

The inside of the lower chamber 124 has a cylindrical shape, and the lower chamber 124 may be formed of metal or metal-alloy. The lower chamber 124 may be continuously connected to the upper chamber 122. A vacuum pump 126 may be connected to the lower chamber 124 to exhaust the lower chamber 124. In addition, a pressure of the lower chamber 124 may be several tens of milliTorr mTorr to several hundred milliTorr. In addition, a pressure of the upper chamber 122 may be higher than the pressure of the lower chamber.

The second baffle 160 may be disposed in the cylindrical portion of the upper chamber 120 to partition the upper chamber 122 and the lower chamber 124. The second baffle 160 may supply the active species of the upper chamber 122 to the lower chamber 124. The second baffle 160 may neutralize capacitively-coupled plasma in the lower chamber 124 to prevent the capacitively-coupled plasma from transmitting the upper chamber 122, and may increase a contact area with the capacitively-coupled plasma.

The second baffle 160 may include: an upper baffle 162 electrically grounded and including a plurality of first through-holes 162a opposing the upper chamber 122; and a lower baffle 164 electrically grounded and spaced apart from the upper baffle 162 and including a plurality of second through-holes 164a. The second through-holes 164a may be disposed to avoid overlapping the first through-holes 162a.

A thickness of the upper baffle 162 may be smaller than a thickness of the lower baffle 164. Accordingly, the upper baffle 162 may provide sufficiently large conductance with the first through-holes 162a due to the small thickness thereof. The lower baffle 164 may increase a contact area with the plasma due to the large thickness thereof.

A diameter of the second through-hole 164a may be more than twice the thickness of plasma sheath between the lower baffle 164 and the plasma. Specifically, the diameter of the second through-hole 164a may be 5 to 10 millimeters. Accordingly, the plasma may permeate into the second through-hole 164a. The second through-holes 164a in the lower baffle 164 may increase a contact area with the plasma. The plasma permeating into the second through-hole 164a may collide with the upper baffle 162 to be neutralized. The upper baffle 162 may further increase the contact area with the plasma.

A gap g between the upper baffle 162 and the lower baffle 164 may be less than or equal to a few millimeters. Specifically, the gap g between the upper baffle 162 and the lower baffle 164 may be about 1 to 5 millimeters. The gap g between the upper baffle and the lower baffle may be sufficiently small to prevent plasma, reaching the upper baffle 162 through the second through-hole 164a, from diffusing in a lateral direction.

A gap d between the substrate holder 132 and a lower surface of the upper baffle 164 may be larger than the gap g between the upper baffle and the lower baffle. The gap g between the substrate holder and the lower surface of the upper baffle may be 10 to 30 millimeters.

The substrate holder 132 may support a substrate 134 and receive power from RF power sources 142 and 146 to generate capacitively-coupled plasma. The substrate holder 132 may include an electrode 136 for an electrostatic chuck. The electrostatic chuck may be supplied with a DC high voltage from an external entity to fix the substrate 134 with electrostatic force. The substrate holder 132 may include a power electrode 135 receiving power from the RF power source. The electrode 136 of the electrostatic chuck may be disposed on the power electrode 135.

The substrate 134 may be a semiconductor substrate, a glass substrate, or a plastic substrate. The semiconductor substrate may be a silicon wafer of 300 mm.

The RF power sources 142 and 146 may provide RF power to the power electrode 135. The RF power sources 142 and 146 may include: a low-frequency RF power source 146 of 13.56 MHz or less; and a high-frequency RF power source 142 of more than 13.56 MHz and less than 60 MHz. A frequency of the low-frequency RF power source 146 may be 400 kHz to 10 MHz. A frequency of the high-frequency RF power source 142 may be 20 MHz to 60 MHz. The RF power sources 142 and 146 may operate in pulse mode or continuous mode.

The low-frequency RF power source 146 may supply low-frequency RF power to the power electrode 135 through a first impedance matching network 148. The high-frequency RF power source 142 may supply low-frequency RF power to the power electrode 135 through a second impedance matching network 144.

A pulse control unit 149 may control the low-frequency RF power source 146 and the high-frequency RF power source 142. Each of the low-frequency RF power and the high-frequency RF power may operate in pulse mode.

The RF power source of the RF power source 142, 146 may generate capacitively-coupled plasma between the substrate 134 and the second baffle 160. A first plasma sheath a may be generated between the substrate and the plasma. Also, a second plasma sheath b may be generated between the second baffle 160 and the plasma. The first plasma sheath a and the second plasma sheath b may be a capacitor in a circuit. A first DC voltage Va may be applied to the first plasma sheath a, and a second DC voltage Vb may be applied to the second plasma sheath b. An area, in which the plasma and the substrate 134 are in contact with each other, is a first area Aa and an area, in which the plasma and the second baffle 160 are in contact with each other, is a second area Ab.

The energy of ions incident on the substrate 134 may depend on the first DC voltage Va. Therefore, the second area Ab in which the second baffle 160 and the plasma are in contact with each other may be increased to increase the first DC voltage Va. That is, the lower baffle 164 may have a second through-hole 164a, large enough for the plasma to permeate thereinto, to increase the second area Ab

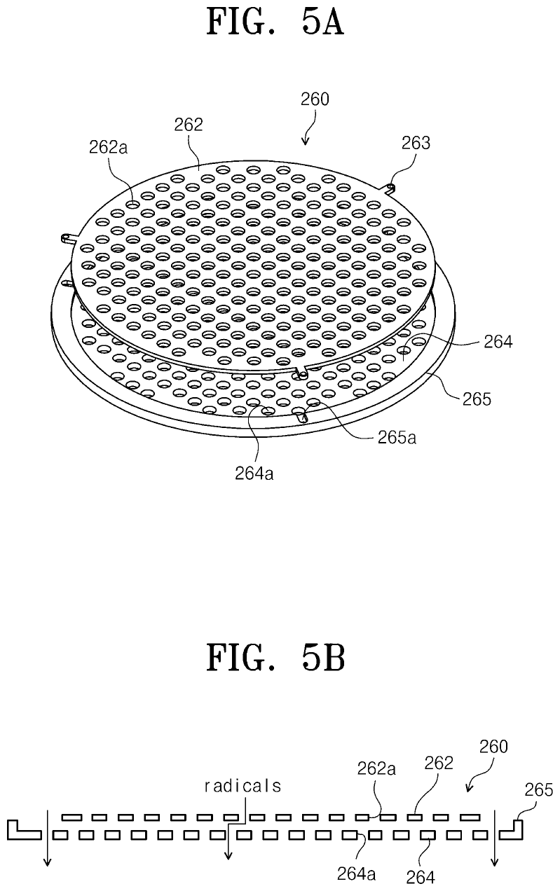

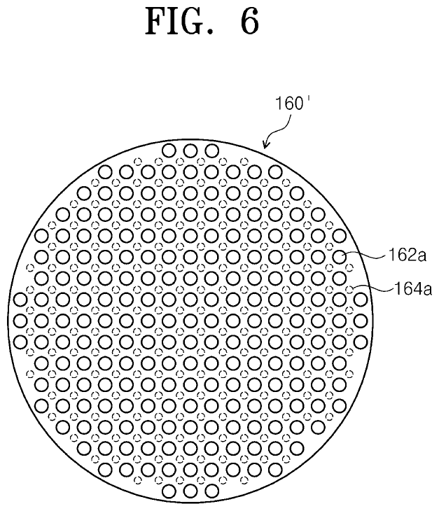

FIG. 5a is a perspective view of a second baffle according to an embodiment of the present disclosure.

FIG. 5b is a cross-sectional view of a second baffle according to an embodiment of the present disclosure.

Referring to FIG. 5a and FIG. 5b, the second baffle 260 may include: an upper baffle 262 electrically grounded and including a plurality of first through-holes 262a facing the upper chamber; and a lower baffle 264 electrically grounded and spaced apart from the upper baffle and including a plurality of second through-holes 264a. The second through-holes 264a may be disposed to avoid overlapping the first through-holes 262a.

A diameter of the upper baffle 262 may be smaller than a diameter of the lower baffle 264. The diameter of the first baffle 152 is about 100 to 150 mm, and the diameter of the second baffle 260 is about 400 mm. The second baffle 260 may have a structure allowing active species to uniformly diffuse at a minimum distance from the substrate. Due to a difference in diameter between the first baffle 152 and the second baffle 260, the density of active species in a center portion of the second baffle 260 may be higher than at an edge thereof. The diameter of the upper baffle 262 may be larger than the diameter of the lower baffle 264 to prevent a non-uniform spatial distribution of active species density in the upper chamber 122 from being transferred to the lower chamber 124. Accordingly, a larger number of active species may flow to an outer portion of the second baffle 260. As a result, a uniform spatial distribution of active species density may be obtained in the lower chamber.

The lower baffle 264 has a ring-shaped projection 265 protruding at an outermost portion, and the ring-shaped projection 265 may include a protrusion 265a protruding for alignment with the upper baffle 262. The upper baffle 262 may have a smaller diameter than the lower baffle 264, but may include a plurality of bridges 263 extending in a radial direction. The bridges 263 may be coupled and fixed to the projection 265a.

FIG. 6 is a plan view of a second baffle according to another example embodiment of the present disclosure.

Referring to FIG. 6, a second baffle 160′ may include: an upper baffle 162 electrically grounded and including a plurality of first through-holes 162a opposing the upper chamber; and a lower baffle 164 electrically grounded and spaced apart from the upper baffle and including a plurality of second through-holes 164a. A diameter of the first through-holes 162a in the upper baffle may be smaller than a diameter of the second through-holes 164a in the lower baffle. The second through-hole 164a may be disposed to avoid overlapping the first through-holes 162a. The diameter of the first through-holes 162a may be smaller than a thickness of the plasma sheath in the second baffle. Accordingly, plasma may be prevented from permeating from a lower portion to an upper portion through the first through-hole 162a. However, active species may freely transmit the first through-holes 162afrom an upper portion to a lower portion. The second through-holes 164a may be disposed to avoid overlapping the first through-holes 162a.

However, when the diameter of the first through-holes 162a is smaller than a thickness of the plasma sheath, the second through-hole 164a may be disposed to overlap the first through-hole 162a. In addition, the number of first through-holes 162a may be sufficiently larger than the number of second through-holes 164a. Accordingly, each of the upper baffle and the lower baffle may provide a similar open area ratio (open area/total area) to provide similar conductance.

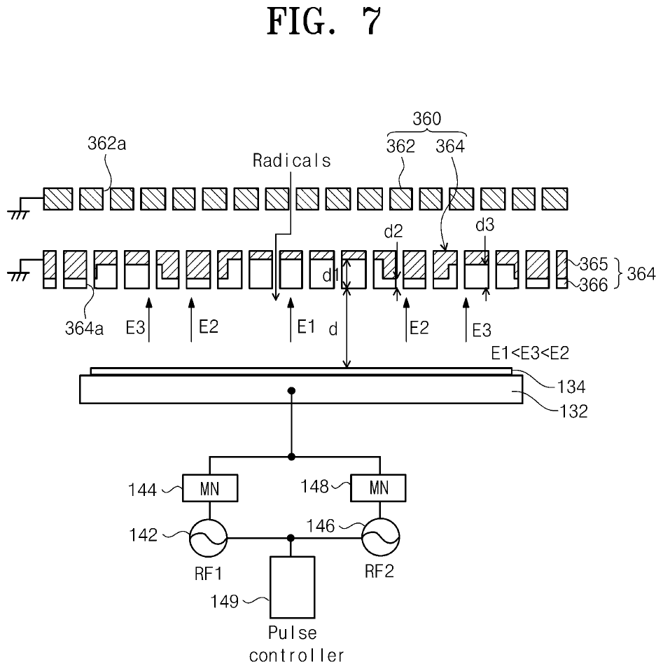

FIG. 7 is a conceptual diagram of a second baffle according to another embodiment of the present disclosure.

FIG. 8 is a cut-away perspective view of a lower baffle of the second baffle of FIG. 7.

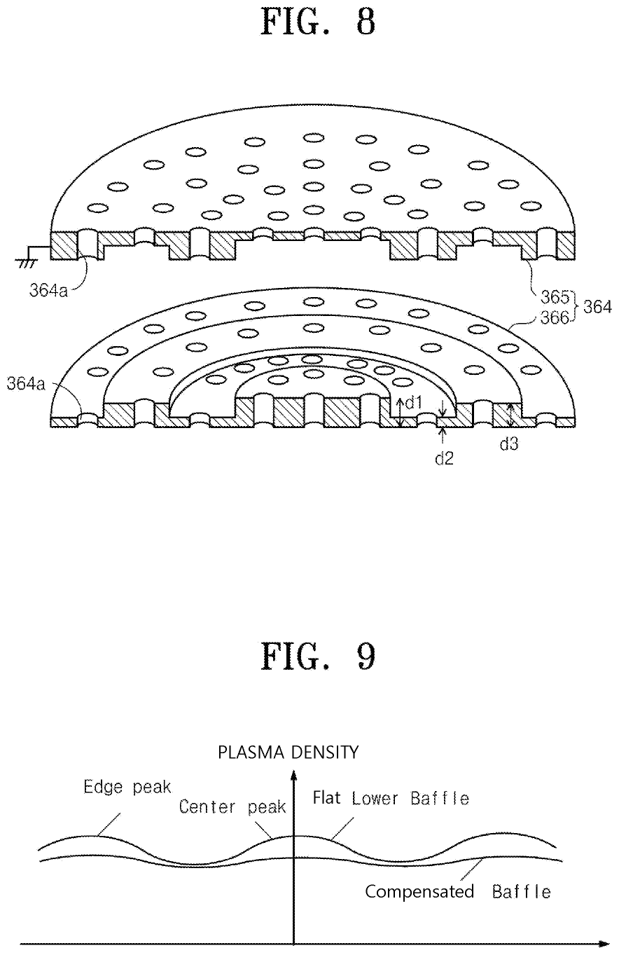

FIG. 9 is a diagram illustrating a change in plasma density by the second baffle of FIG. 7.

Referring to FIGS. 7 to 9, the second baffle 360 includes: an upper baffle 363 electrically grounded and including a plurality of first through-holes 362a opposing the upper chamber; and a lower baffle 364 electrically grounded and spaced apart from the upper baffle and including a plurality of second through-holes 364a.

The lower baffle 364 may include a perforated plate 365 formed of a conductor and a compensation plate 366 disposed below the perforated plate 365 and being an insulator having a dielectric constant or a semiconductor. The second through-holes 364a of the lower baffle 364 may be disposed to penetrate through the perforated plate 365 and the compensation plate 366. The lower baffle 364 may have a constant thickness, and a thickness of the perforated plate 365 may vary depending on a location. A thickness of the compensation plate 366 may vary depending on a location to maintain the thickness of the lower baffle 364 constant.

The compensation plate 366 may include at least one of silicon, silicon oxide, silicon nitride, and silicon oxynitride. The thickness of the compensation plate 366 may be greatest in at least one of a central region and/or an edge region. The central region may have a circular shape, and the edge region may be a ring shape.

As a frequency of the RF power source 142 increases, a standing wave effect or a harmonic effect may occur. The standing wave effect and the harmonic effect may increase as the frequency increases, and may form a center peak and/or an edge peak of plasma density.

As the frequency of the RF power source 142 increases, the plasma density may increase and electron temperature may decrease, so that various process environments may be established as compared to the low-frequency RF power source.

Conventionally, a surface step may be provided on a power electrode applied with RF power source to spatially adjust the magnitude of an electric field in capacitively-coupled plasma. However, the surface step of the power electrode may cause contaminants to be deposited to form particles. Even when the power source has a surface curvature, it may be difficult to manufacture such a curvature electrode and such a curvature electrode may interfere with a flow of the fluid to cause difficulty in providing a spatially uniform process.

According to an embodiment, the perforated plate 365 of the lower baffle 364 acting as a grounded electrode may have a curvature or step on a lower surface thereof. The surface curvature or step of the perforated plate 365 may spatially adjust a gap d between the lower baffle 364 and the substrate holder 132 applied with the RF power source to adjust the magnitude of the electric field at each location.

The lower baffle 364 may have a second through-hole 364a. When a thickness of the lower baffle 364 varies depending on a location, conductance of the second through-hole 364a may vary. The lower baffle 364 may have a multilayer structure and may be planarized with a constant thickness to suppress an effect on a fluid flow in a discharge space while maintaining conductance of the second through-hole 364a constant.

Specifically, the lower baffle 364 may include a perforated plate 365, formed of a conductor, and a compensation plate 366 disposed below the perforated plate and being an insulator having a dielectric constant or a semiconductor. The compensation plate 366 may be an insulator having a dielectric constant or a semiconductor. The second through-hole 364a of the lower baffle may be disposed to penetrate through the perforated plate and the compensation plate. Accordingly, a lower surface of the lower baffle 364 may be the same plane.

In a discharge region, magnitudes of electric fields E1, E, and E3 may be determined by thicknesses d1, d2, d3 of the compensation layer 366, a dielectric constant of the compensation layer, and a height d of the discharge region. That is, as the dielectric constant of the compensation layer 366 decreases, the magnitude of the electric field E1 may be easily changed. Accordingly, a material of the compensation layer 366 may be silicon oxide, silicon nitride, silicon oxynitride, aluminum oxide, or silicon.

The thickness of the compensation layer 366 may be about ½ to 1/10 of the height d of the discharge region. For example, when the height d of the discharge region is 10 mm, the maximum thickness d1 of the compensation layer 366 may be 5 mm to 1 mm. The thicker the compensation layer 366, the lower the electric field strength in the corresponding discharge region. When d1>d3>d2, then E1<E3<E2. Accordingly, the thickness of the compensation layer 366 may be selected depending on a location to suppress the center peak and/or edge peak of the plasma density.

According to a modified embodiment, the thickness of the compensation layer 366 changes abruptly depending on a location, but may change gradually.

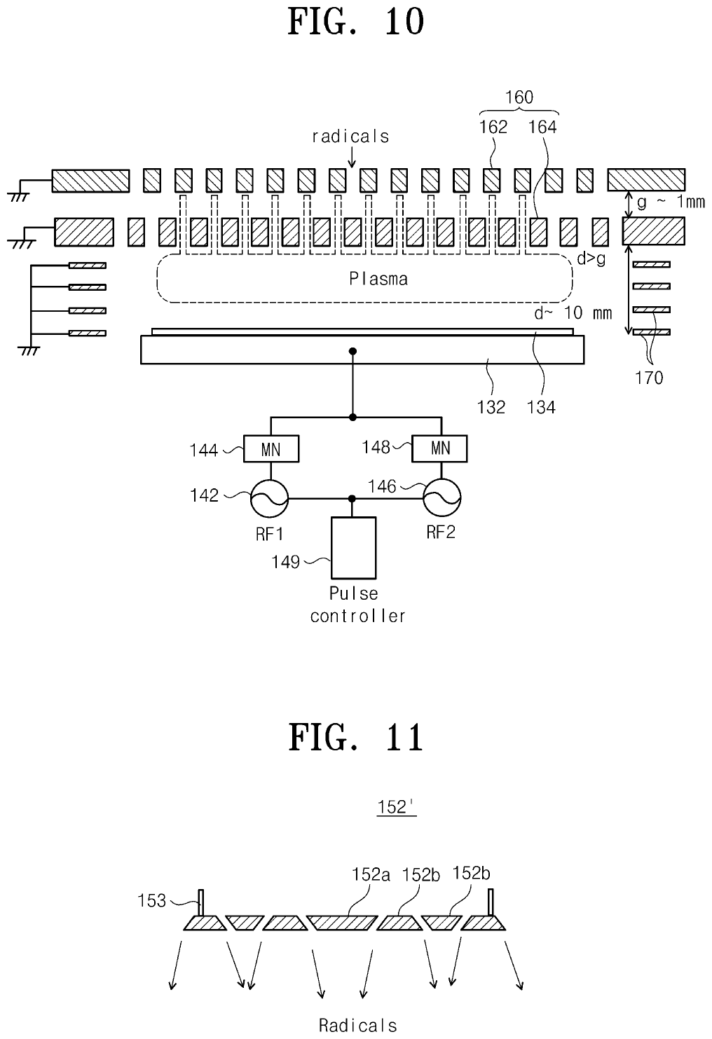

FIG. 10 is a conceptual diagram of a substrate treatment apparatus according to another embodiment of the present disclosure.

Referring to FIG. 10, a plasma substrate processing apparatus 100 according to an embodiment may include: a remote plasma generator 110 generating plasma and active species; an upper chamber 122 having an opening 120a connected to the output port 114 of the remote plasma generator 110 and receiving and diffusing the active species of the remote plasma generator 110; a first baffle 152 disposed in the opening of the upper chamber 122; a lower chamber 124 receiving the active species diffused in the upper chamber 122; a second baffle 160 partitioning the upper chamber 122 and the lower chamber 124 and transmitting the active species; a substrate holder 134 supporting a substrate 134 disposed in the lower chamber 160; and RF power sources 142 and 146 playing RF power to the substrate holder 134.

In a cylindrical cavity structure surrounding a parallel plate capacitor, a resonant frequency of standing wave may be inversely proportional to a radius of the lower chamber 124. Accordingly, as a diameter of the lower chamber 124 increases, the resonant frequency may decrease. For example, when the radius of the lower chamber is 0.3 m, the resonant frequency may be about 300 MHz. When the frequency of the RF power source 142 is 100 MHz, third harmonics may match the resonant frequency to significantly generate a standing wave effect. Accordingly, the radius of the lower chamber does not need to be reduced to increase the resonant frequency of the resonator by the lower chamber.

At least one ground ring 170 may be disposed to surround the discharge region to effectively reduce the radius of the lower chamber. Accordingly, the resonant frequency may increase, the standing wave effect may be reduced, and an area of the ground surface that is in contact with plasma may increase. The resonant frequency is achieved by the harmonics of the RF power source 142, so that when the frequency of the RF power source 142 is used below 60 MHz, the standing wave effect may be reduced.

A ground ring 170 may be disposed below the second baffle 160 to surround the plasma between the substrate holder 132 and the second baffle 160, and may have a washer shape. An inner diameter of the ground ring 170 may be larger than an outer diameter of the substrate holder 132. The ground ring 170 may limit a discharge space to limit a space in which the plasma diffuses. In addition, the ground ring 170 may be grounded to increase a ground area and increase a DC bias voltage applied to the substrate 134. The ground rings 170 may be disposed to vertically stacked and to be spaced apart from each other, so that neutral gas may be exhausted to a space between the ground rings 170. A material of the ground ring 170 may be a conductive material, and may be metal or metal alloy.

FIG. 11 is a cross-sectional view of a first baffle according to another embodiment of the present invention.

Referring to FIG. 11, the first baffle 152′ may include: a disk 152a having an inclined outer surface; and a plurality of ring plates 152b having an inclined inner surface and an inclined outer surface and disposed to surround the disk 152a at a predetermined gap from the disk 152a.

A space between the disk 152a and the ring plate 152b and a space between the ring plates 152b may form a concentric slit. Active species, passing through the concentric slit between the disk 152a and the ring plate 152b, may diffuse toward a center of an upper chamber.

Active species, passing through the concentric slit between the ring plates 152b, may diffuse toward a wall of the upper chamber. The first baffle 152′ may spatially distribute the active species to achieve rapid diffusion. Accordingly, a height of the upper chamber 122 may decrease.

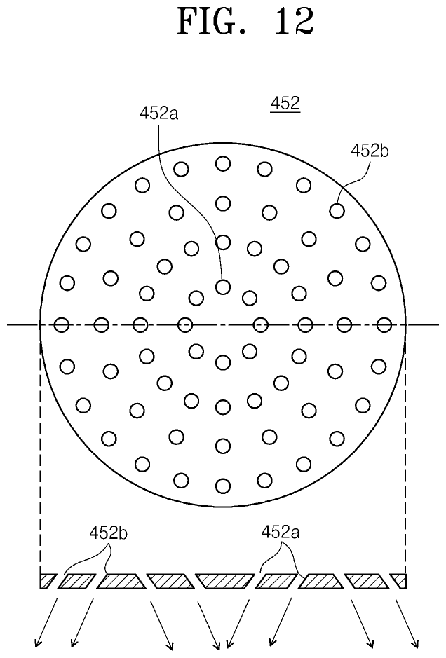

FIG. 12 is a cross-sectional view of a first baffle according to another embodiment of the present invention.

Referring to FIG. 12, a first baffle 452 may include a plurality of through-holes 452a and 452b in an oblique direction. The through-holes 452a in a center region may be sloped to inject active species in a direction of a central axis. The through-holes 452b in an edge region may be inclined to inject active species toward a wall of an upper chamber. The first baffle 452 may spatially distribute the active species to achieve rapid diffusion. Accordingly, a height of the upper chamber may decrease.

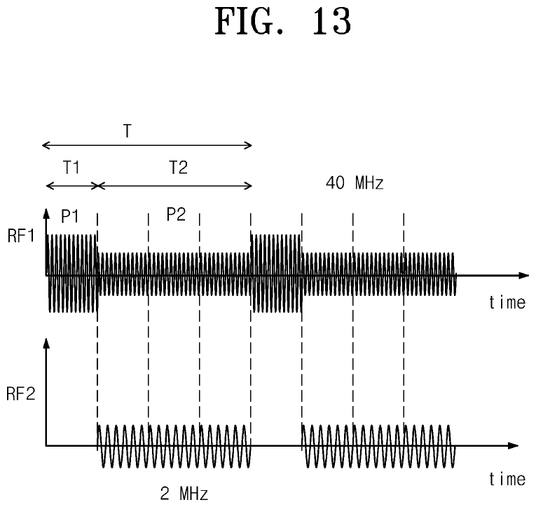

FIG. 13 is a diagram illustrating a low-frequency RF signal and a high-frequency RF signal of an RF power source according to another embodiment of the present disclosure.

Referring to FIG. 13, a high-frequency RF signal RF1 of a high-frequency RF power source 122 may repeat a high-power interval T1 and a low-power interval T2 with a constant period T. The high-power interval T1 may increase plasma density in a discharge region. The low-power interval T2 may suppress complete extinguishment of the plasma, so that the high-frequency RF power source 122 may independently control stable plasma generation in the next high-power interval T1. Since the active species are separately supplied through a second baffle, power and frequency of the high-frequency RF power source 122 may operate under conditions in which the plasma density is increased. The frequency of the high-frequency RF power source 122 may be 13.56 MHz to 60 MHz.

In the high-power interval T1, a low-frequency RF signal RF2 of the low-frequency RF power source 146 may be turned off. In the low-power interval T2, a low-frequency RF signal RF2 of the low-frequency RF power source may be provided. The low-frequency RF signal RF2 may independently control energy of ions. Plasma properties may be independently controlled to be appropriate to each process. Since a high DC bias is applied to a substrate due to an increase in grounding area by a second baffle and/or a ground ring, power of the low-frequency RF power source 146 may be relatively reduced. In addition, energy of the ions by the low-frequency RF signal RF2 may have high energy.

Although the present disclosure and its advantages have been described in detail, it should be understood that various changes, substitutions and alterations can be made herein without departing from the spirit and scope of the disclosure as defined by the following claims.

1. A plasma substrate treatment apparatus comprising:
a remote plasma generator generating plasma and active species;
an upper chamber having an opening connected to an output port of the remote plasma generator and receiving and diffuses the active species of the remote plasma generator;
a first baffle disposed on the opening of the upper chamber;
a lower chamber receiving the diffused active species from the upper chamber;
a second baffle partitioning the upper chamber and the lower chamber and transmitting the active species;
a substrate holder supporting a substrate disposed in the lower chamber; and
a radio-frequency (RF) power source applying RF power to the substrate holder.

2. The plasma substrate treatment apparatus as set forth in claim 1, wherein the second baffle comprises:
an upper baffle electrically grounded and comprising a plurality of first through-holes opposing the upper chamber; and
a lower baffle electrically grounded and spaced apart from the upper baffle and comprising a plurality of second through-holes.

3. The plasma substrate treatment apparatus as set forth in claim 2, wherein the second through-holes are disposed to avoid overlapping the first through-holes.

4. The plasma substrate treatment apparatus as set forth in claim 2, wherein a diameter of the second through-hole is greater than twice a thickness of the plasma sheath between the lower baffle and the plasma, and the plasma permeates into the second through-hole.

5. The plasma substrate treatment apparatus as set forth in claim 2, wherein
a gap between the upper baffle and the lower baffle is less than or equal to several millimeters, and
a gap between the substrate holder and a lower surface of the upper baffle is greater than the gap between the upper baffle and the lower baffle.

6. The plasma substrate treatment apparatus as set forth in claim 2, wherein
a diameter of the first through-hole of the upper baffle is smaller than a diameter of the second through-hole of the lower baffle.

7. The plasma substrate treatment apparatus as set forth in claim 6, wherein
the second through-hole is disposed to avoid overlapping the first through-hole.

8. The plasma substrate treatment apparatus as set forth in claim 1, wherein
a diameter of the upper baffle is smaller than a diameter of the lower baffle.

9. The plasma substrate treatment apparatus as set forth in claim 1, wherein
the first baffle comprises:
a disk having an inclined outer surface; and
a ring plate having an inclined inner surface and an inclined outer surface and disposed to surround the disk at a predetermined gap from the disk,
the outer surface of the disc has an outer diameter increasing with height, and
the inner surface of the ring plate has an inner diameter increasing with height.

10. The plasma substrate treatment apparatus as set forth in claim 9, wherein
the disk and the ring plate are fixed by a plurality of bridges, and
the ring plate is fixed to the upper chamber by a plurality of columns.

11. The plasma substrate treatment apparatus as set forth in claim 9, wherein
the first baffle comprises a plurality of through-holes,
through-holes disposed in a center portion of the first baffle are holes inclined toward a central axis, and
through-holes disposed at an edge of the first baffle are holes inclined towards an outer side.

12. The plasma substrate treatment apparatus as set forth in claim 1, further comprising:
at least one ground ring,
wherein
the ground ring is disposed below the second baffle to surround plasma between the substrate holder and the second baffle and has a ring shape, and
an inner diameter of the ground ring is greater than an outer diameter of the substrate holder.

13. The plasma substrate treatment apparatus as set forth in claim 1, wherein
the second baffle comprises:
an upper baffle electrically grounded and comprising a plurality of first through-holes opposing the upper chamber; and
a lower baffle electrically grounded and spaced apart from the upper baffle and comprising a plurality of second through-holes,
the lower baffle comprises:
a perforated plate formed of a conductor; and
a compensation plate disposed below the perforated plate and being an insulator having a dielectric constant or a semiconductor, and
the second through-holes of the lower baffle is disposed to penetrate through the perforated plate and the compensation plate.

14. The plasma substrate treatment apparatus as set forth in claim 13, wherein
the lower baffle has a constant thickness,
a thickness of the perforated plate varies depending on a location, and
a thickness of the compensation plate varies depending on a location to maintain the thickness of the lower baffle constant.

15. The plasma substrate treatment apparatus as set forth in claim 13, wherein
the compensation plate comprises at least one of silicon, silicon oxide, silicon nitride, or silicon oxynitride.

16. The plasma substrate treatment apparatus as set forth in claim 14, wherein
the thickness of the compensation plate is greatest in at least one of a central region and an edge region,
the central region has a circular shape, and
the edge region has a ring shape.

17. The plasma substrate treatment apparatus as set forth in claim 14, wherein
the RF power source comprises:
a low-frequency RF power source of 13.56 MHz or less; and
a high-frequency RF power source of more than 13.56 MHz and less than 60 MHz.

18. The plasma substrate treatment apparatus as set forth in claim 14, further comprising:
a pulse control controlling the low-frequency RF power and the high-frequency RF power,
wherein
each of the low-frequency RF power and the high-frequency RF power operates in pulse mode.

19. The plasma substrate treatment apparatus as set forth in claim 1, wherein
the remote plasma generator is an inductively-coupled plasma source comprising an induction coil wound around a dielectric cylinder.

20. The plasma substrate treatment apparatus as set forth in claim 1, wherein
the diameter of the output port of the remote plasma generator ranges from 50 millimeters to 150 millimeters,
the upper chamber has a truncated cone shape, and
the opening of the upper chamber is disposed in a truncated portion.
